(19) United States
(12) Patent Application Publication
(10) Pub. No.: US 2025/0104933 A1
(43) Pub. Date: Mar. 27, 2025

(54) CAPACITOR ELEMENT

(71) Applicant: Murata Manufacturing Co., Ltd., Nagaokakyo-shi (JP)

(72) Inventor: Sachiko YOSHINO, Nagaokakyo-shi (JP)

(21) Appl. No.: 18/973,271

(22) Filed: Dec. 9, 2024

Related U.S. Application Data
(63) Continuation of application No. PCT/JP2023/032360, filed on Sep. 5, 2023.

(30) Foreign Application Priority Data
Sep. 30, 2022 (JP) 2022-157833

(51) Int. Cl. H01G 9/15; H01G 9/012; H01G 9/10

(52) U.S. Cl. CPC H01G 9/15; H01G 9/012; H01G 9/10

(57) ABSTRACT

A capacitor element that includes: a capacitor part including: an anode plate having a core and a porous part on at least one major face of the core, a dielectric layer on a surface of the porous part, and a cathode layer on a surface of the dielectric layer; and a sealing layer that seals the capacitor part, wherein a surface of the sealing layer has a slit.

### CROSS REFERENCE TO RELATED APPLICATIONS

The present application is a continuation of International application No. PCT/JP2023/032360, filed Sep. 5, 2023, which claims priority to Japanese Patent Application No. 2022-157833, filed Sep. 30, 2023, the entire contents of each of which are incorporated herein by reference.

### TECHNICAL FIELD

The present disclosure relates to a capacitor element.

### BACKGROUND ART

Patent Document 1 discloses a capacitor array. The capacitor array includes a plurality of solid electrolytic capacitor elements into which a single solid electrolytic capacitor sheet is divided, a sheet-shaped first sealing layer, and a sheet-shaped second sealing layer. The solid electrolytic capacitor sheet includes an anode plate, a porous layer, a dielectric layer, and a cathode layer. The anode plate is made of a valve metal. The porous layer is disposed on at least one major face of the anode plate. The dielectric layer is disposed on a surface of the porous layer. The cathode layer includes a solid electrolyte layer disposed on a surface of the dielectric layer. The solid electrolytic capacitor sheet has a first major face and a second major face, which are opposite from each other in the thickness direction. The first major face of each of the solid electrolytic capacitor elements is disposed on the first sealing layer. The second sealing layer is positioned to cover the solid electrolytic capacitor elements on the first sealing layer from a side corresponding to the second major face. The solid electrolytic capacitor elements are divided from each other by a slit-shaped sheet removal part.
Patent Document 1: Japanese Unexamined Patent Application Publication No. 2020-167361

### SUMMARY OF THE DISCLOSURE

Patent Document 1 describes that a stress relaxation layer may be disposed between each solid electrolytic capacitor element and the first sealing layer or the second sealing layer. According to Patent Document 1, the presence of the stress relaxation layer at the above-mentioned location makes it possible to reduce stress acting between the inside and outside of the capacitor array, without compromising the capabilities (e.g., resistance and blocking performance) required for individual conductor and insulating parts disposed on the outermost portion of the solid electrolytic capacitor elements.

FIGS. 25, 27, and 29 in Patent Document 1 each illustrate a cross-section of a capacitor array including a stress relaxation layer. Simply providing the stress relaxation layer at the location illustrated in each of FIGS. 25, 27, and 29 in Patent Document 1, however, may still allow occurrence of delamination in the effective capacitance portion of the solid electrolytic capacitor elements, for example, delamination of the cathode layer from the anode plate.

The above-mentioned problem arises not only with structures including a plurality of capacitor parts disposed inside the sealing layer, but also with structures including a single capacitor part disposed inside the sealing layer.

The present disclosure is directed to addressing the above-mentioned problem. It is accordingly an object of the present disclosure to provide a capacitor element that allows for reduced delamination in the effective capacitance portion thereof.

A capacitor element according to the present disclosure includes: an anode plate having a core and a porous part on at least one major face of the core, a dielectric layer on a surface of the porous part, and a cathode layer on a surface of the dielectric layer; and a sealing layer that seals the capacitor part, wherein a surface of the sealing layer has a slit.

The present disclosure makes it possible to provide a capacitor element that allows for reduced delamination in the effective capacitance portion.

### BRIEF DESCRIPTION OF THE DRAWINGS

FIG. 1 is a schematic cross-sectional view of an example of a capacitor element according to the present disclosure.

FIG. 2A is a plan view, taken along a line A, of the capacitor element illustrated in FIG. 1.

FIG. 2B is a plan view, taken along a line B, of the capacitor element illustrated in FIG. 1.

FIG. 3 is a schematic cross-sectional view of a capacitor element according to a first modification of the present disclosure.

FIG. 4 is an enlarged view of a portion indicated at “a” in FIG. 3.

FIG. 5 is a schematic cross-sectional view of a capacitor element according to a second modification of the present disclosure.

FIG. 6 is a schematic plan view of an example of a capacitor element assembly.

### DESCRIPTION OF THE PREFERRED EMBODIMENTS

A capacitor element according to the present disclosure is now described below. The present disclosure is not limited to the features described below but may be modified as appropriate without departing from the scope of the present disclosure. The present disclosure also encompasses combinations of individual preferred features described hereinbelow.

As used herein, terms indicative of the relationship between elements (e.g., “perpendicular”, “parallel”, and “orthogonal”), and terms indicative of a shape of an element are not intended to represent only their strict meanings but are meant to also include their substantial equivalents, for example, equivalents with deviations or differences of about a few percent.

The drawings below are schematic in nature, and dimensions, scales such as the horizontal-to-vertical ratio, or other details in the drawings may differ from those of the actual product. In the drawings, identical or corresponding features are identified with identical reference signs. In the drawings, identical elements are designated by identical reference signs to avoid repetitive description.

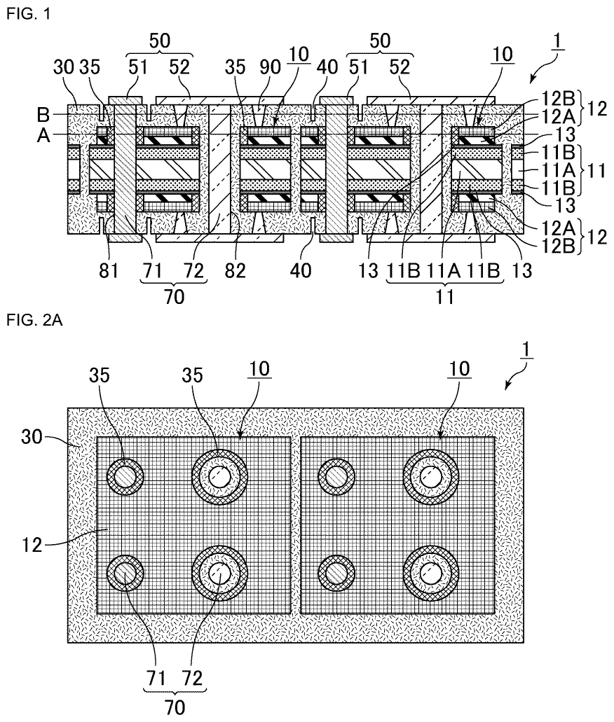

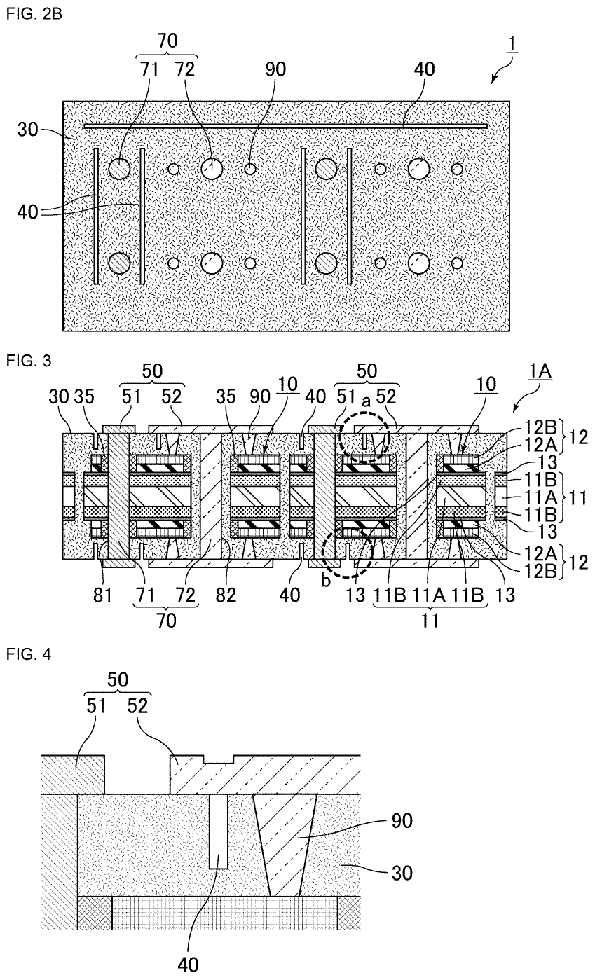

FIG. 1 is a schematic cross-sectional view of an example of a capacitor element according to the present disclosure. FIG. 2A is a plan view, taken along a line A, of the capacitor element illustrated in FIG. 1. FIG. 2B is a plan view, taken along a line B, of the capacitor element illustrated in FIG. 1.

A capacitor element 1 illustrated in FIGS. 1, 2A and 2B includes a capacitor part 10, and a sealing layer 30 that seals the capacitor part 10.

In the example illustrated in FIGS. 1, 2A, and 2B, two capacitor parts 10 are disposed inside the sealing layer 30. The number of capacitor parts 10 to be disposed inside the sealing layer 30 is not particularly limited. A single capacitor part 10 or a plurality of capacitor parts 10 may be disposed inside the sealing layer 30.

The capacitor part 10 includes an anode plate 11, a dielectric layer 13, and a cathode layer 12. The anode plate 11 has a core 11A, and a porous part 11B disposed on at least one major face of the core 11A. The dielectric layer 13 is disposed on a surface of the porous part 11B. The cathode layer 12 is disposed on a surface of the dielectric layer 13. The capacitor part 10 thus constitutes an electrolytic capacitor. In the example illustrated in FIG. 1, the anode plate 11 has the porous part 11B on both major faces of the core 11A. Alternatively, however, the anode plate 11 may have the porous part 11B on only one of the major faces of the core 11A.

The cathode layer 12 includes, for example, a solid electrolyte layer 12A disposed on the surface of the dielectric layer 13. Preferably, the cathode layer 12 further includes a conductor layer 12B disposed on a surface of the solid electrolyte layer 12A. If the cathode layer 12 includes the solid electrolyte layer 12A, the capacitor part 10 constitutes a solid electrolytic capacitor.

As illustrated in FIG. 1, the sealing layer 30 is preferably disposed on both major faces of the capacitor part 10 that are opposite from each other in the thickness direction of the capacitor part 10. The sealing layer 30 protects the capacitor part 10.

The sealing layer 30 may be made up of only one layer, or may be made up of two or more layers. If the sealing layer 30 is made up of two or more layers, each layer may be made of the same material, or may be made of a different material.

The sealing layer 30 is formed through, for example, a method such as thermocompression bonding of an insulating resin sheet, or application and subsequent heat-curing of an insulating resin paste, in such a way that the sealing layer 30 seals the capacitor part 10.

A surface of the sealing layer 30 has a slit 40. As illustrated in FIGS. 1 and 2B, the surface of the sealing layer 30 preferably has a plurality of slits 40.

Due to the presence of the slit 40 in the surface of the sealing layer 30, stress due to warpage or other causes can be reduced. This makes it possible to reduce delamination in the effective capacitance portion. This in turn makes it possible to reduce deterioration of ESR.

If the sealing layer 30 is disposed on each major face of the capacitor part 10, only the surface of the sealing layer 30 disposed on one major face may have the slit 40. Preferably, however, the surface of the sealing layer 30 disposed on each major face has the slit 40. If the surface of the sealing layer 30 disposed on each major face of the capacitor part 10 has the slit 40, the slit 40 at one major face of the capacitor part 10 and the slit 40 at the other major face may be identical in features such as location, shape in cross-section, shape in plan view, or depth, or a subset or all of such slits 40 may differ in these features.

The slit 40 is preferably disposed at a position where the slit 40 does not contact the cathode layer 12. If the slit 40 is disposed at a position where the slit 40 does not contact the cathode layer 12, this helps to ensure that even when delamination occurs, such delamination is allowed to occur not in the vicinity of the cathode layer 12 but preferentially in the vicinity of the slit 40. This makes it possible to reduce delamination in the effective capacitance portion. This in turn makes it possible to reduce deterioration of ESR.

If the cathode layer 12 includes the solid electrolyte layer 12A and the conductor layer 12B, the slit 40 is preferably disposed at a position where the slit 40 does not contact the conductor layer 12B. If the surface of the sealing layer 30 has a plurality of slits 40, it is preferable that at least one slit 40 be disposed at a position where the slit 40 does not contact the conductor layer 12B.

The capacitor element 1 may further include an outer electrode layer 50 disposed on the surface of the sealing layer 30.

The outer electrode layer 50 includes, for example, a first outer electrode layer 51, and a second outer electrode layer 52. The first outer electrode layer 51 is electrically connected to the anode plate 11. The second outer electrode layer 52 is electrically connected to the cathode layer 12.

The capacitor element 1 may further include an extended conductor. The extended conductor is disposed inside the sealing layer 30, and extended to the surface of the sealing layer 30.

Non-limiting examples of the extended conductor include a through-hole conductor 70, and a via-conductor 90.

The extended conductor includes, for example, a first extended conductor, and a second extended conductor. The first extended conductor is electrically connected to the anode plate 11. The second extended conductor is electrically connected to the cathode layer 12.

A non-limiting example of the first extended conductor is a first through-hole conductor 71. Inside the cathode layer 12, a single first through-hole conductor 71 may be disposed, or two or more first through-hole conductors 71 may be disposed.

Non-limiting examples of the second extended conductor include a second through-hole conductor 72, and the via-conductor 90. Inside the cathode layer 12, a single second through-hole conductor 72 may be disposed, or two or more second through-hole conductors 72 may be disposed. Inside the cathode layer 12, a single via-conductor 90 may be disposed, or two or more via-conductors 90 may be disposed.

In the example illustrated in FIG. 1, the capacitor element 1 includes the first through-hole conductor 71 serving as the first extended conductor. In that case, the slit 40 is preferably disposed at a position where the slit 40 contacts neither of the cathode layer 12 and the first through-hole conductor 71. Disposing the slit 40 at a position where the slit 40 does not contact the first extended conductor such as the first through-hole conductor 71 as described above makes it possible to reduce delamination at the first extended conductor. This in turn makes it possible to reduce deterioration of ESR.

Further, in the example illustrated in FIG. 1, the capacitor element 1 includes the first outer electrode layer 51. In that case, the slit 40 is preferably disposed at a position where the slit 40 contacts none of the cathode layer 12, the first through-hole conductor 71, and the first outer electrode layer 51. Disposing the slit 40 at a position where the slit 40 does not contact the first outer electrode layer 51 as described above makes it possible to reduce delamination at the first outer electrode layer 51. This in turn makes it possible to reduce deterioration of ESR.

In the example illustrated in FIG. 1, the capacitor element 1 includes the second through-hole conductor 72 and the via-conductor 90 that each serve as the second extended conductor. In that case, the slit 40 is preferably disposed at a position where the slit 40 contacts none of the cathode layer 12, the second through-hole conductor 72, and the via-conductor 90. Disposing the slit 40 at a position where the slit 40 does not contact the second extended conductor such as the second through-hole conductor 72 or the via-conductor 90 as described above makes it possible to reduce delamination at the second extended conductor. This in turn makes it possible to reduce deterioration of ESR.

Further, in the example illustrated in FIG. 1, the capacitor element 1 includes the second outer electrode layer 52. In that case, the slit 40 is preferably disposed at a positioned where the slit 40 contacts none of the cathode layer 12, the second through-hole conductor 72, the via-conductor 90, and the second outer electrode layer 52. Disposing the slit 40 at a position where the slit 40 does not contact the second outer electrode layer 52 as described above makes it possible to reduce delamination at the second outer electrode layer 52. This in turn makes it possible to reduce deterioration of ESR.

For a case in which the slit 40 is disposed at a position where the slit 40 does not contact the second extended conductor, the slit 40 may be disposed at a position where the slit 40 contacts neither of the second through-hole conductor 72 and the via-conductor 90, or may be disposed at a position where the slit 40 does not contact only one of the second through-hole conductor 72 and the via-conductor 90.

Examples of the method for forming the slit 40 in the surface of the sealing layer 30 include, but are not particularly limited to, laser machining, and etching. If a large-sized sheet including a plurality of capacitor elements 1 is to be used to simultaneously produce the capacitor elements 1, the slit 40 may be formed after the large-sized sheet is split into the capacitor elements 1 (i.e., into discrete parts), or before the large-sized sheet is split into the capacitor elements 1 (i.e., with the large-sized sheet in its pre-split state). In the latter case, the slit 40 can be formed in accordance with the tendency of, for example, warpage or stress generation, in addition to the configuration of the capacitor element 1 serving as a product.

The slit 40 to be provided may be a slit that is positioned perpendicularly to the surface of the sealing layer 30, may be a slit that is positioned obliquely to the surface of the sealing layer 30, or may be a slit that is bent inside the sealing layer 30. Such different slits 40 may coexist.

In plan view seen in the thickness direction of the cathode layer 12, the slit 40 may be disposed at a position overlapping the cathode layer 12, or may be disposed at a position not overlapping the cathode layer 12. If the surface of the sealing layer 30 has a plurality of slits 40, the slits 40 may be disposed at both a position overlapping the cathode layer 12 and a position not overlapping the cathode layer 12.

In plan view seen in the thickness direction of the cathode layer 12, the slit 40 disposed at a position overlapping the cathode layer 12 is, for example, positioned not to overlap the outer electrode layer 50. For example, if the outer electrode layer 50 includes the first outer electrode layer 51 and the second outer electrode layer 52, then in plan view seen in the thickness direction of the cathode layer 12, the slit 40 disposed at a position overlapping the cathode layer 12 may be positioned to overlap neither of the first outer electrode layer 51 and the second outer electrode layer 52.

Alternatively, in plan view seen in the thickness direction of the cathode layer 12, the slit 40 disposed at a position overlapping the cathode layer 12 may be positioned to overlap the outer electrode layer 50. For example, if the outer electrode layer 50 includes the first outer electrode layer 51 and the second outer electrode layer 52, then in plan view seen in the thickness direction of the cathode layer 12, the slit 40 disposed at a position overlapping the cathode layer 12 may be positioned to overlap both the first outer electrode layer 51 and the second outer electrode layer 52, or may be positioned to overlap one of the first outer electrode layer 51 and the second outer electrode layer 52.

FIG. 3 is a schematic cross-sectional view of a capacitor element according to a first modification of the present disclosure.

In a portion indicated at “a” of a capacitor element 1A illustrated in FIG. 3, the slit 40 disposed at a position overlapping the cathode layer 12 is positioned to overlap the outer electrode layer 50 (the second outer electrode layer 52 in this case).

FIG. 4 is an enlarged view of the portion indicated at “a” in FIG. 3.

As illustrated in FIG. 4, the outer electrode layer 50 (the second outer electrode layer 52 in this case) located at a position overlapping the slit 40 may have a step. More specifically, the outer electrode layer 50 (the second outer electrode layer 52 in this case) located at a position overlapping the slit 40 may be recessed. The recessed portion of the outer electrode layer 50 is not particularly limited in terms of its features such as shape in cross-section, shape in plan view, or depth.

As in the portions indicated at “a” and “b” in FIG. 3, the slit 40 at the front side of the capacitor part 10 and the slit 40 at the back side of the capacitor part 10 do not have to lie on the same straight line. In the example illustrated in FIG. 3, the slit 40 located at a position overlapping the cathode layer 12 in the portion indicated at “a”, and the slit 40 located at a position overlapping the cathode layer 12 in the portion indicated at “b” do not lie on the same straight line. In another example, the slits 40 located at positions different from the above-mentioned positions may be the slits 40 that are located at the front and back sides of the capacitor part 10 and that do not lie on the same straight line.

If the surface of the sealing layer 30 has a plurality of slits 40, each slit 40 may have identical in depth, or a subset or all of the slits 40 may differ in depth.

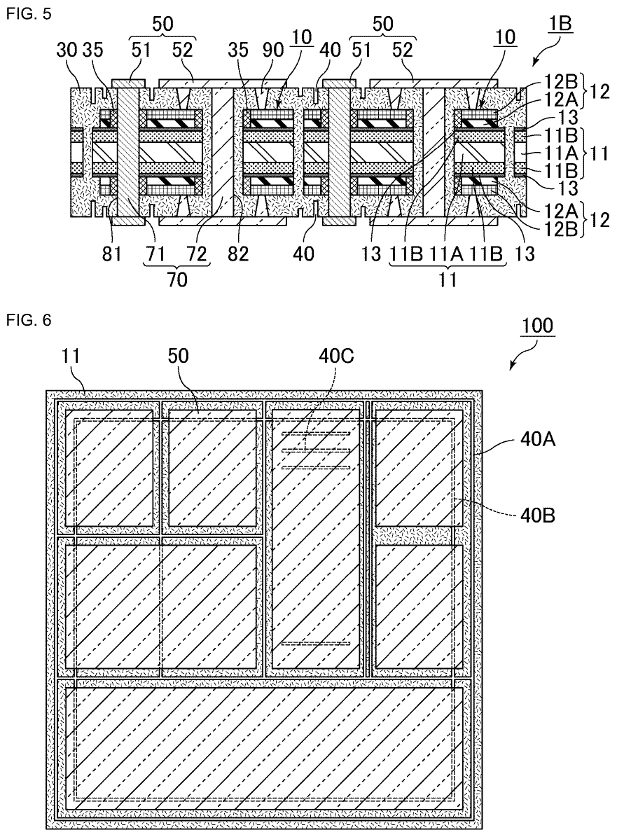

FIG. 5 is a schematic cross-sectional view of a capacitor element according to a second modification of the present disclosure.

In a capacitor element 1B illustrated in FIG. 5, the slits 40 differ in depth. In the example illustrated in FIG. 5, the slits 40 differ in depth at both major faces of the capacitor part 10. Alternatively, however, the slits 40 may differ in depth at only one major face of the capacitor part 10.

FIG. 6 is a schematic plan view of an example of a capacitor element assembly.

A capacitor element assembly 100 illustrated in FIG. 6 is a large-sized sheet including a plurality of capacitor elements. As illustrated in FIG. 6, slits 40A, 40B, and 40C may be provided at any locations in the capacitor element assembly 100. Each of the slits 40A, 40B, and 40C does not have to be provided continuously but may be, for example, provided discontinuously at required locations.

The capacitor element assembly 100 tends to experience stress acting on the corners. The anode plate 11 is thus more susceptible to deformation in the outer edge portion than in the central portion. Accordingly, it is preferable that many slits 40A be provided in the outer edge portion of the anode plate 11.

The slit 40B may be provided under the outer electrode layer 50. In FIG. 6, the slit 40B provided under the outer electrode layer 50 is represented by dashed lines.

If the capacitor element assembly 100 includes outer electrode layers 50 that have different areas, it is preferable that many slits 40C be provided at the outer electrode layer 50 having a large area. In that case, a region susceptible to the influence of stress within the plane of the effective capacitance portion may be provided with many slits 40C.

The capacitor element assembly 100 configured as described above is cut to obtain the capacitor element having a slit.

As described above, in the capacitor element according to the present disclosure, the slit may be located closer to the outer edge portion of the anode plate than to the central portion of the anode plate. If the surface of the sealing layer has a plurality of slits, it may suffice that at least one slit be located closer to the outer edge portion of the anode plate than to the central portion of the anode plate. If the surface of the sealing layer has a single slit, it may suffice that the slit be located closer to the outer edge portion of the anode plate than to the central portion of the anode plate.

In the capacitor element according to the present disclosure, the slit may be located closer to the outer electrode layer having a relatively large area than to the outer electrode layer having a relatively small area. If the surface of the sealing layer has a plurality of slits, it may suffice that at least one slit be located closer to the outer electrode layer having a relatively large area than to the outer electrode layer having a relatively small area. If the surface of the sealing layer has a single slit, it may suffice that the slit be located closer to the outer electrode layer having a relatively large area than to the outer electrode layer having a relatively small area.

For example, the outer electrode layer having a relatively large area may be the first outer electrode layer electrically connected to the anode plate, or the second outer electrode layer electrically connected to the cathode layer. Likewise, the outer electrode layer having a relatively small area may be the first outer electrode layer electrically connected to the anode plate, or the second outer electrode layer electrically connected to the cathode layer. In this case, the combination of the outer electrode layer having a relatively large area and the outer electrode layer having a relatively small area may be the combination of the first outer electrode layer and the first outer electrode layer, the combination of the first outer electrode layer and the second outer electrode layer, the combination of the second outer electrode layer and the first outer electrode layer, or the combination of the second outer electrode layer and the second outer electrode layer.

Reference is now made to a detailed configuration of each of the capacitor elements 1, 1A, and 1B.

Non-limiting examples of the shape of the capacitor part 10 in plan view seen in the thickness direction include: a polygon such as a rectangle (a square or an oblong), a non-rectangular quadrilateral, a triangle, a pentagon, or a hexagon; a circle; an ellipse; and a combination of these shapes. Alternatively, the shape of the capacitor part 10 in plan view may be, for example, an L-shape, a C-shape (U-shape), or a stepped shape.

The anode plate 11 is preferably made of a so-called valve metal that exhibits valve action. Non-limiting examples of the valve metal include: single metals such as aluminum, tantalum, niobium, titanium, and zirconium; and an alloy containing at least one of such single metals. Among these, aluminum or an aluminum alloy is preferred.

The anode plate 11 is preferably flat plate-shaped, and more preferably foil-shaped. Thus, as used herein, the term “plate-shaped” is meant to include “foil-shaped.”

It may suffice for the anode plate 11 to have the porous part 11B on at least one major face of the core 11A. That is, the anode plate 11 may have the porous part 11B only on one major face of the core 11A, or may have the porous part 11B on both major faces of the core 11A. The porous part 11B is preferably a porous layer formed on the surface of the core 11A, and more preferably an etched layer.

Prior to etching, the anode plate 11 preferably has a thickness of greater than or equal to 60 μm and less than or equal to 200 μm. The thickness of the core 11A that remains unetched after the etching is preferably greater than or equal to 15 μm and less than or equal to 70 μm. The porous part 11B has a thickness designed in accordance with the required withstand voltage and the required electrostatic capacity. The combined thickness of the porous parts 11B on opposite sides of the core 11A is preferably greater than or equal to 10 μm and less than or equal to 180 μm.

The porous part 11B preferably has a pore size of greater than or equal to 10 nm and less than or equal to 600 nm. The pore size of the porous part 11B refers to the median diameter D50 as measured with a mercury porosimeter. The pore size of the porous part 11B can be controlled through, for example, adjustment of various conditions used for etching.

The dielectric layer 13 disposed on the surface of the porous part 11B is porous, which reflects the surface condition of the porous part 11B. The dielectric layer 13 thus has a surface with minute irregularities. The dielectric layer 13 is preferably made of an oxide coating of the valve metal mentioned above. For example, if an aluminum foil is used as the anode plate 11, the dielectric layer 13 made of an oxide coating can be formed through application of anodization (also referred to as chemical conversion coating) to the surface of the aluminum foil in an aqueous solution containing, for example, ammonium adipate.

The thickness of the dielectric layer 13, which is designed in accordance with the required withstand voltage and the required electrostatic capacity, is preferably greater than or equal to 10 nm and less than or equal to 100 nm.

For a case in which the cathode layer 12 includes the solid electrolyte layer 12A, non-limiting examples of the material constituting the solid electrolyte layer 12A include conductive polymers such as polypyrroles, polythiophenes, and polyanilines. Preferred among these are polythiophenes, particularly poly(3, 4-ethylenedioxythiophene), which is called PEDOT. The conductive polymers mentioned above may contain a dopant such as polystyrene sulfonic acid (PSS). The solid electrolyte layer 12A preferably includes an inner layer that fills the pores (depressions) of the dielectric layer 13, and an outer layer that covers the dielectric layer 13.

The thickness of the solid electrolyte layer 12A from the surface of the porous part 11B is preferably greater than or equal to 2 μm and less than or equal to 20 μm.

Non-limiting examples of the method used to form the solid electrolyte layer 12A include: a method of forming a polymerized film of poly(3, 4-ethylenedioxythiophene) on the surface of the dielectric layer 13 by use of a treatment solution containing monomers such as 3,4-ethylenedioxythiophene; and a method of applying a dispersion of polymers such as poly(3, 4-ethylenedioxythiophene) onto the surface of the dielectric layer 13, and then drying the dispersion.

The solid electrolyte layer 12A can be formed in a predetermined region by coating of the surface of the dielectric layer 13 with the above-mentioned treatment solution or dispersion through a method such as sponge transfer, screen printing, application with a dispenser, or inkjet printing.

If the cathode layer 12 includes the conductor layer 12B, the conductor layer 12B includes at least one of a conductive resin layer or a metal layer. The conductor layer 12B may be made up of only a conductive resin layer or only a metal layer. The conductor layer 12B preferably covers the entire surface of the solid electrolyte layer 12A.

A non-limiting example of the conductive resin layer is a conductive adhesive layer containing at least one conductive filler selected from the group consisting of a silver filler, a copper filler, a nickel filler, and a carbon filler.

Non-limiting examples of the metal layer include a metal plating film, and a metal foil. The metal layer is preferably made of at least one metal selected from the group consisting of nickel, copper, silver, and an alloy containing such a metal as its major component. The term “major component” as used herein means an elemental component with the largest weight proportion.

The conductor layer 12B may include, for example, a carbon layer, and a copper layer. The carbon layer is disposed on a surface of the solid electrolyte layer 12A. The copper layer is disposed on a surface of the carbon layer.

The carbon layer is provided to electrically and mechanically connect the solid electrolyte layer 12A and the copper layer to each other. The carbon layer can be formed in a predetermined region by coating of the surface of the solid electrolyte layer 12A with a carbon paste through a method such as sponge transfer, screen printing, application with a dispenser, or inkjet printing. In this case, the stacking of the copper layer at the next step is preferably performed while the carbon layer is in its pre-dried, viscous state. The carbon layer preferably has a thickness of greater than or equal to 2 μm and less than or equal to 20 μm.

The copper layer can be formed in a predetermined region by coating of the surface of the carbon layer with a copper paste through a method such as sponge transfer, screen printing, application with a dispenser, or inkjet printing. The carbon layer preferably has a thickness of greater than or equal to 2 μm and less than or equal to 20 μm.

The sealing layer 30 is made of an insulating material. In this case, the sealing layer 30 is preferably made of insulating resin.

Non-limiting examples of the insulating resin constituting the sealing layer 30 include epoxy resin and phenolic resin.

Preferably, the sealing layer 30 further includes a filler.

A non-limiting example of the filler included in the sealing layer 30 is an inorganic filler such as silica particles or alumina particles.

For example, a layer such as a stress relaxation layer or a moisture barrier film may be disposed between the capacitor part 10 and the sealing layer 30.

The through-hole conductor 70 preferably includes at least one of the first through-hole conductor 71, which is electrically connected to the anode plate 11, or the second through-hole conductor 72, which is electrically connected to the cathode layer 12.

The first through-hole conductor 71 extends through the capacitor part 10 and the sealing layer 30 in the thickness direction.

It may suffice that the first through-hole conductor 71 be disposed on at least the inner wall surface of a first through-hole 81, which extends through the capacitor part 10 and the sealing layer 30 in the thickness direction. The first through-hole conductor 71 may be disposed only on the inner wall surface of the first through-hole 81, or may be disposed in the entire interior of the first through-hole 81.

The first through-hole conductor 71 is preferably electrically connected at the inner wall surface of the first through-hole 81 to the anode plate 11. More specifically, the first through-hole conductor 71 is preferably electrically connected to an end face of the anode plate 11 that faces the inner wall surface of the first through-hole 81 in the in-plane direction. The anode plate 11 is thus electrically led out externally via the first through-hole conductor 71.

The core 11A and the porous part 11B are preferably exposed at an end face of the anode plate 11 that is electrically connected to the first through-hole conductor 71. In this case, in addition to the core 11A, the porous part 11B is also electrically connected to the first through-hole conductor 71.

When viewed in the thickness direction, the first through-hole conductor 71 is preferably electrically connected to the anode plate 11 across the entire circumference of the first through-hole 81. This facilitates reduced connection resistance between the anode plate 11 and the first through-hole conductor 71, and consequently facilitates reduced ESR.

The first through-hole conductor 71 is formed as follows, for example. First, the first through-hole 81, which extends through the capacitor part 10 and the sealing layer 30 in the thickness direction, is formed through machining such as drilling or laser machining. Then, the inner wall surface of the first through-hole 81 is metallized with a metallic material containing a low-resistance metal such as copper, gold, or silver to thereby form the first through-hole conductor 71. In forming the first through-hole conductor 71, the machining is facilitated by, for example, metallizing the inner wall surface of the first through-hole 81 through a process such as electroless copper plating or electrolytic copper plating. Other than the method of metallizing the inner wall surface of the first through-hole 81, another method that may be used to form the first through-hole conductor 71 is to fill the first through-hole 81 with a material such as a metallic material or a composite of a metal and resin.

An anode connection layer may be disposed between the anode plate 11 and the first through-hole conductor 71 in the in-plane direction. That is, the anode plate 11 and the first through-hole conductor 71 may be electrically connected to each other via the anode connection layer.

As described above, the anode connection layer is disposed between the anode plate 11 and the first through-hole conductor 71 in the in-plane direction. The anode connection layer thus serves as a barrier layer for the anode plate 11, more specifically, a barrier layer for the core 11A and for the porous part 11B. The presence of the anode connection layer serving as a barrier layer for the anode plate 11 reduces the risk of the anode plate 11 dissolving during treatment with a chemical solution that is performed to form the outer electrode layer 50 (e.g., the first outer electrode layer 51). This in turn reduces the risk of the chemical solution entering the capacitor part 10, and consequently facilitates improved reliability.

The anode connection layer preferably includes a layer containing nickel as a major component. This allows for reduced damage to the metal (e.g., aluminum) constituting the anode plate 11, and consequently facilitates improved barrier properties of the anode connection layer with respect to the anode plate 11.

No anode connection layer may be disposed between the anode plate 11 and the first through-hole conductor 71 in the in-plane direction. In this case, the first through-hole conductor 71 may be directly connected to the end face of the anode plate 11.

If the first through-hole conductor 71 is disposed only on the inner wall surface of the first through-hole 81, the first through-hole 81 may be provided with a resin-filled part filled with a resin material. In that case, the resin-filled part is located in a space inside the first through-hole 81 that is surrounded by the first through-hole conductor 71. The presence of the resin-filled part results in elimination of space inside the first through-hole 81. This leads to reduced risk of delamination of the first through-hole conductor 71.

The first outer electrode layer 51 is electrically connected to the anode plate 11. In the example illustrated in FIG. 1, the first outer electrode layer 51 is disposed on the surface of the first through-hole conductor 71, and serves as a connection terminal for the capacitor part 10. In the example illustrated in FIG. 1, the first outer electrode layer 51 is electrically connected to the anode plate 11 via the first through-hole conductor 71, and serves as a connection terminal for the anode plate 11.

A non-limiting example of the material constituting the first outer electrode layer 51 is a metallic material containing a low-resistance metal such as copper, gold, or silver. In this case, the first outer electrode layer 51 is formed by, for example, plating applied on the surface of the first through-hole conductor 71.

From the viewpoint of improving the adhesion between the first outer electrode layer 51 and another component, which in this case is the adhesion between the first outer electrode layer 51 and the first through-hole conductor 71, the first outer electrode layer 51 may be made of a mixture of resin and at least one conductive filler selected from the group consisting of a silver filler, a copper filler, a nickel filler, and a carbon filler.

The second through-hole conductor 72 extends through the capacitor part 10 and the sealing layer 30 in the thickness direction.

It may suffice that the second through-hole conductor 72 be disposed on at least the inner wall surface of a second through-hole 82, which extends through the capacitor part 10 and the sealing layer 30 in the thickness direction. The second through-hole conductor 72 may be disposed only on the inner wall surface of the second through-hole 82, or may be disposed in the entire interior of the second through-hole 82.

The second through-hole conductor 72 is formed as follows, for example. First, a through-hole that extends through the capacitor part 10 in the thickness direction is formed through machining such as drilling or laser machining. Subsequently, the through-hole mentioned above is filled with an insulating material. The portion of the through-hole that is now filled with the insulating material is then subjected to machining such as drilling or laser machining to thereby form the second through-hole 82. At this time, the second through-hole 82 is formed with a diameter less than the diameter of the through-hole filled with the insulating material. This results in a state in which the insulating material exists between the previously formed through-hole and the second through-hole 82 in the in-plane direction. Subsequently, the inner wall surface of the second through-hole 82 is metallized with a metallic material containing a low-resistance metal such as copper, gold, or silver to thereby form the second through-hole conductor 72. In forming the second through-hole conductor 72, the machining is facilitated by, for example, metallizing the inner wall surface of the second through-hole 82 through a process such as electroless copper plating or electrolytic copper plating. Other than the method of metallizing the inner wall surface of the second through-hole 82, another method that may be used to form the second through-hole conductor 72 is to fill the second through-hole 82 with a material such as a metallic material or a composite of a metal and resin.

If the second through-hole conductor 72 is disposed only on the inner wall surface of the second through-hole 82, the second through-hole 82 may be provided with a resin-filled part filled with a resin material. In that case, the resin-filled part is located in a space inside the second through-hole 82 that is surrounded by the second through-hole conductor 72. The presence of the resin-filled part results in elimination of space inside the second through-hole 82. This leads to reduced risk of delamination of the second through-hole conductor 72.

The second outer electrode layer 52 is electrically connected to the cathode layer 12. In the example illustrated in FIG. 1, the second outer electrode layer 52 is disposed on the surface of the second through-hole conductor 72, and serves as a connection terminal for the capacitor part 10.

A non-limiting example of the material constituting the second outer electrode layer 52 is a metallic material containing a low-resistance metal such as copper, gold, or silver. In this case, the second outer electrode layer 52 is formed by, for example, plating applied on the surface of the second through-hole conductor 72.

From the viewpoint of improving the adhesion between the second outer electrode layer 52 and another component, which in this case is the adhesion between the second outer electrode layer 52 and the second through-hole conductor 72, the second outer electrode layer 52 may be made of a mixture of resin and at least one conductive filler selected from the group consisting of a silver filler, a copper filler, a nickel filler, and a carbon filler.

Although the material constituting the first outer electrode layer 51, and the material constituting the second outer electrode layer 52 are preferably identical to each other at least in kind, these materials may be different from each other.

In the example illustrated in FIG. 1, the capacitor parts 10 are each provided with the first outer electrode layer 51 electrically connected to the anode plate 11, and the second outer electrode layer 52 electrically connected to the cathode layer 12. Alternatively, however, at least one of the first outer electrode layer 51 or the second outer electrode layer 52 may be common to the capacitor parts 10.

In the example illustrated in FIG. 1, the first outer electrode layer 51 and the second outer electrode layer 52 are disposed on both major faces of the sealing layer 30. Alternatively, however, the first outer electrode layer 51 and the second outer electrode layer 52 may be disposed only on one major face of the sealing layer 30.

Although not illustrated in FIG. 1, the through-hole conductor 70 may include a third through-hole conductor, which is electrically connected to neither of the anode plate 11 and the cathode layer 12.

The via-conductor 90 extends through the sealing layer 30 in the thickness direction, and is connected to the cathode layer 12 and the second outer electrode layer 52.

A non-limiting example of the material constituting the via-conductor 90 is a metallic material containing a low-resistance metal such as copper, gold, or silver.

The via-conductor 90 is formed through, for example, application of a plating of the above-mentioned metallic material to the inner wall surface of a through-hole that extends through the sealing layer 30 in the thickness direction, or filling of the through-hole with a conductive paste and the subsequent application of heat treatment.

In the example illustrated in FIG. 1, the second through-hole conductor 72 is electrically connected to the cathode layer 12 via the second outer electrode layer 52 and the via-conductor 90.

In the example illustrated in FIG. 1, the second outer electrode layer 52 is electrically connected to the cathode layer 12 via the via-conductor 90, and serves as a connection terminal for the cathode layer 12.

If the through-hole conductor 70 is disposed inside the sealing layer 30, the capacitor part 10 preferably further includes a mask layer 35 disposed at least at one major face of the anode plate 11 and around the through-hole conductor 70.

In the example illustrated in FIGS. 1 and 2A, the mask layer 35 is disposed between the first through-hole conductor 71 and the cathode layer 12. In the example illustrated in FIGS. 1 and 2A, the space between the second through-hole conductor 72 and the capacitor part 10 is filled with the insulating material of, for example, the sealing layer 30, and the mask layer 35 is disposed between the insulating material and the cathode layer 12.

Although not illustrated in FIGS. 1 and 2A, the capacitor part 10 may further include a mask layer disposed at least at one major face of the anode plate 11 and surrounding the periphery of the cathode layer 12. Surrounding the periphery of the cathode layer 12 with the mask layer ensures insulation between the anode plate 11 and the cathode layer 12, and consequently prevents short-circuiting therebetween. Although the mask layer may surround part of the periphery of the cathode layer 12, the mask layer preferably surrounds the entire periphery of the cathode layer 12.

The mask layer such as the mask layer 35 is made of an insulating material. In this case, the mask layer is preferably made of insulating resin.

Non-limiting examples of the insulating resin constituting the mask layer such as the mask layer 35 include polyphenyl sulfone resin, polyether sulfone resin, cyanate ester resin, fluororesin (e.g., tetrafluoroethylene or tetrafluoroethylene-perfluoroalkyl vinyl ether copolymer), polyimide resin, polyamide-imide resin, epoxy resin, and derivatives or precursors of these resins.

The mask layer such as the mask layer 35 may be made of the same resin as the resin constituting the sealing layer 30. Unlike the sealing layer 30, if the mask layer contains an inorganic filler, this can adversely affect the effective capacitance portion of the capacitor part 10. Therefore, the mask layer is preferably made up of resin alone.

The mask layer such as the mask layer 35 can be formed in a predetermined region by, for example, coating of the surface of the porous part 11B with a mask material, such as a composition including insulating resin, through a method such as sponge transfer, screen printing, application with a dispenser, or inkjet printing.

The mask layer such as the mask layer 35 may be formed at the porous part 11B before the dielectric layer 13 is formed, or may be formed at the porous part 11B after the dielectric layer 13 is formed.

The embodiments mentioned above are not intended to limit the capacitor element according to the present disclosure. With regard to the configuration, manufacturing conditions, or other details of the capacitor element, various modifications or variations can be made within the scope of the present disclosure.

The capacitor element according to the present disclosure may include, inside the sealing layer, a single capacitor part or a plurality of capacitor parts.

If the capacitor element according to the present disclosure includes a plurality of capacitor parts inside the sealing layer, it may suffice that adjacent capacitor elements be physically separated from each other. Accordingly, adjacent capacitor parts may be electrically separated from each other, or may be electrically connected to each other. The area where adjacent capacitor parts are separated from each other is preferably filled with the insulating material of, for example, the sealing layer. The spacing between adjacent capacitor parts may be constant in the thickness direction, or may decrease in the thickness direction.

If the capacitor element according to the present disclosure includes a plurality of capacitor parts disposed inside the sealing layer, the capacitor parts may be disposed in a manner such that the capacitor parts are arranged side by side in the in-plane direction, may be disposed in a manner such that the capacitor parts are stacked in the thickness direction, or may be disposed in a combination of the two manners mentioned above. The capacitor parts may be arranged in a regular fashion, or may be arranged in an irregular fashion. In terms of size, shape, and other features, each of the capacitor elements may be identical, or a subset or all of the capacitor elements may be different. Although the capacitor elements are preferably identical in configuration, a subset of the capacitor elements may be different in configuration.

The capacitor element according to the present disclosure can be suitably used as a constituent material of a composite electronic component. Such a composite electronic component includes, for example, the capacitor element according to the present disclosure, an outer electrode layer, and an electronic component. The outer electrode layer is disposed at the surface of the sealing layer of the capacitor element, and electrically connected to each of the anode plate and the cathode layer of the capacitor element. The electronic component is electrically connected to the outer electrode layer.

In the composite electronic component, the electronic component connected to the outer electrode layer may be a passive element, or may be an active element. Both a passive element and an active element may be connected to the outer electrode layer, or only one of a passive element and an active element may be connected to the outer electrode layer. A composite of a passive element and an active element may be connected to the outer electrode layer.

A non-limiting example of the passive element is an inductor. Non-limiting examples of the active element include a memory, a graphical processing unit (GPU), a central processing unit (CPU), a micro processing unit (MPU), and a power management IC (PMIC).

The capacitor element according to the present disclosure is generally in sheet form. This means that the capacitor element of the composite electronic component can be handled like a mounting substrate so that electronic components can be mounted onto the capacitor element. Further, if the electronic components to be mounted onto the capacitor element are formed in sheet form, the capacitor element and each electronic component can be electrically connected in the thickness direction via a through-hole conductor that extends through the electronic component in the thickness direction. As a result, an active element and a passive element can be constructed as if these elements constitute a unified module.

For example, a switching regulator can be formed by electrically connecting the capacitor element according to the present disclosure between a voltage regulator including a semiconductor active element, and a load that receives supply of a converted direct-current voltage.

In the composite electronic component, a circuit layer may be formed at one face of a capacitor matrix sheet, which is a sheet where a plurality of the capacitor elements according to the present disclosure are laid out, and the circuit layer may be connected to a passive element or an active element.

The capacitor element according to the present disclosure may be disposed in a cavity that is formed in a substrate in advance, and after the cavity is filled with resin, a circuit layer may be formed on the resin. Another electronic component (a passive component or an active component) may be mounted in another cavity provided in the same substrate.

In an alternative possible configuration, the capacitor element according to the present disclosure is mounted onto a smooth carrier such as a wafer or glass, and after an outer layer part made of resin is formed, a circuit layer is formed, and then the circuit layer is connected to a passive element or an active element.

The following features are disclosed herein.

<1> A capacitor element including: an anode plate having a core and a porous part on at least one major face of the core, a dielectric layer on a surface of the porous part, and a cathode layer on a surface of the dielectric layer; and a sealing layer that seals the capacitor part, wherein a surface of the sealing layer has a slit.

<2> The capacitor element according to <1>, in which the slit is positioned so as to not contact the cathode layer.

<3> The capacitor element according to <2>, further including a first extended conductor inside the sealing layer and electrically connected to the anode plate, the first extended conductor extending to a surface of the sealing layer, in which the slit is positioned such that the slit contacts neither of the cathode layer and the first extended conductor.

<4> The capacitor element according to <3>, further including a first outer electrode layer on a surface of the sealing layer, the first outer electrode layer electrically connected to the anode plate via the first extended conductor, in which the slit is positioned such that the slit contacts none of the cathode layer, the first extended conductor, and the first outer electrode layer.

<5> The capacitor element according to any one of <2> to <4>, further including a second extended conductor inside the sealing layer and electrically connected to the cathode layer, the second extended conductor extending to a surface of the sealing layer, in which the slit is positioned such that the slit contacts neither of the cathode layer and the second extended conductor.

<6> The capacitor element according to <5>, further including a second outer electrode layer on a surface of the sealing layer, the second outer electrode layer electrically connected to the cathode layer via the second extended conductor, in which the slit is positioned such that the slit contacts none of the cathode layer, the second extended conductor, and the second outer electrode layer.

<7> The capacitor element according to any one of <1> to <6>, in which the slit is located closer to an outer edge portion of the anode plate than to a central portion of the anode plate.

<8> The capacitor element according to any one of <1> to <7>, further including an outer electrode layer on a surface of the sealing layer and electrically connected to the anode plate or the cathode layer, in which in a plan view seen in a thickness direction of the cathode layer, the outer electrode layer includes a first outer electrode layer having a relatively large area, and a second outer electrode layer having a relatively small area, and in which the slit is located closer to the first outer electrode layer than to the second outer electrode layer.

<9> The capacitor element according to any one of <1> to <8>, in which the cathode layer includes a solid electrolyte layer on a surface of the dielectric layer.

### REFERENCE SIGNS LIST

1, 1A, 1B capacitor element
10 capacitor part
11 anode plate
11A core
11B porous part
12 cathode layer
12A solid electrolyte layer
12B conductor layer
13 dielectric layer
30 sealing layer
35 mask layer
40, 40A, 40B, 40C slit
50 outer electrode layer
51 first outer electrode layer
52 second outer electrode layer
70 through-hole conductor
71 first through-hole conductor
72 second through-hole conductor
81 first through-hole
82 second through-hole
90 via-conductor
100 capacitor element assembly

1. A capacitor element comprising:
a capacitor part including:
an anode plate having a core and a porous part on at least one major face of the core,
a dielectric layer on a surface of the porous part, and
a cathode layer on a surface of the dielectric layer; and
a sealing layer that seals the capacitor part,
wherein a surface of the sealing layer has a slit.

2. The capacitor element according to claim 1, wherein the slit is positioned so as to not contact the cathode layer.

3. The capacitor element according to claim 2, further comprising:
a first extended conductor inside the sealing layer and electrically connected to the anode plate, the first extended conductor extending to a surface of the sealing layer,
wherein the slit is positioned such that the slit contacts neither of the cathode layer nor the first extended conductor.

4. The capacitor element according to claim 3, further comprising:
a first outer electrode layer on a surface of the sealing layer, the first outer electrode layer electrically connected to the anode plate via the first extended conductor,
wherein the slit is positioned such that the slit contacts none of the cathode layer, the first extended conductor, and the first outer electrode layer.

5. The capacitor element according to claim 3, further comprising:
a second extended conductor inside the sealing layer and electrically connected to the cathode layer, the second extended conductor extending to a surface of the sealing layer,
wherein the slit is positioned such that the slit contacts neither of the cathode layer nor the second extended conductor.

6. The capacitor element according to claim 5, further comprising:
a second outer electrode layer on a surface of the sealing layer, the second outer electrode layer electrically connected to the cathode layer via the second extended conductor,
wherein the slit is positioned such that the slit contacts none of the cathode layer, the second extended conductor, and the second outer electrode layer.

7. The capacitor element according to claim 6, further comprising:
a first outer electrode layer on a surface of the sealing layer, the first outer electrode layer electrically connected to the anode plate via the first extended conductor,
wherein the slit is positioned such that the slit contacts none of the cathode layer, the first extended conductor, and the first outer electrode layer.

8. The capacitor element according to claim 2, further comprising:
a second extended conductor inside the sealing layer and electrically connected to the cathode layer, the second extended conductor extending to a surface of the sealing layer,
wherein the slit is positioned such that the slit contacts neither of the cathode layer nor the second extended conductor.

9. The capacitor element according to claim 8, further comprising:
a second outer electrode layer on a surface of the sealing layer, the second outer electrode layer electrically connected to the cathode layer via the second extended conductor,
wherein the slit is positioned such that the slit contacts none of the cathode layer, the second extended conductor, and the second outer electrode layer.

10. The capacitor element according to claim 1, wherein the slit is located closer to an outer edge portion of the anode plate than to a central portion of the anode plate.

11. The capacitor element according to claim 1, further comprising:
an outer electrode layer on a surface of the sealing layer and electrically connected to the anode plate or the cathode layer,
wherein, in a plan view seen in a thickness direction of the cathode layer, the outer electrode layer includes a first outer electrode layer having a relatively large area, and a second outer electrode layer having a relatively small area, and
wherein the slit is located closer to the first outer electrode layer than to the second outer electrode layer.

12. The capacitor element according to claim 1, wherein the cathode layer includes a solid electrolyte layer on a surface of the dielectric layer.

13. The capacitor element according to claim 1, wherein the slit is perpendicular to the surface of the sealing layer.

14. The capacitor element according to claim 1, wherein, in a plan view in a thickness direction of the cathode layer, the slit overlaps the cathode layer.

15. The capacitor element according to claim 1, wherein, in a plan view in a thickness direction of the cathode layer, the slit does not overlap the cathode layer.

16. The capacitor element according to claim 1, wherein the surface of the sealing layer has a plurality of the slits.

17. The capacitor element according to claim 16, wherein the plurality of slits are positioned such that a first slit of the plurality of slits overlaps the cathode layer and a second slit of the plurality of slits does not overlap the cathode layer.

18. The capacitor element according to claim 16, wherein the plurality of slits include slits with different depths.

19. The capacitor element according to claim 1, further comprising:
an outer electrode layer on a surface of the sealing layer and electrically connected to the anode plate or the cathode layer,
wherein, in a plan view in a thickness direction of the cathode layer, the slit is positioned so as to overlap the cathode layer and the outer electrode layer.

20. The capacitor element according to claim 19, wherein the outer electrode layer includes a step at a position overlapping the slit.
